(19) United States
(12) Patent Application Publication
(10) Pub. No.: US 2008/0093565 A1
(43) Pub. Date: Apr. 24, 2008

(54) Charged particle beam system and its specimen holder

(75) Inventors: Toshie Yaguchi, Omitama (JP); Takeo Kamino, Hitachinaka (JP); Takahito Hashimoto, Hitachinaka (JP)

Correspondence Address: MCDERMOTT WILL & EMERY LLP, 600 13TH STREET, N.W., WASHINGTON, DC, 20005-3096, US

(73) Assignee: HITACHI HIGH-TECHNOLOGIES CORPORATION

(21) Appl. No.: 11/976,240

(22) Filed: Oct. 23, 2007

(30) Foreign Application Priority Data
Oct. 23, 2006 (JP) 2006-287206

(51) Int. Cl. H01J 37/26; H01J 37/20; H01J 37/32

(52) U.S. Cl. 250/440.11; 250/311; 250/455.11

(57) ABSTRACT

In a charged particle beam device and a specimen holder for the charged particle beam device each of which comprises a mechanism for blowing with a gas at least partially a specimen to be observed, the mechanism includes small flow rate gas spout openings arranged opposed to each other through the specimen with a small distance between the specimen and each of the small flow rate gas spout openings.

### BACKGROUND OF THE INVENTION

The present invention relates to a charged particle beam system for using a charged particle beam to observe a specimen and a specimen holder for the charged particle beam system, particularly to a charged particle beam system usable for observing a reaction process of the specimen surrounded by an environmental gas of very small volume, and the specimen holder for such system.

In the charged particle beam system, the specimen may be observed while being heated to a high temperature or being cooled, or at normal temperatures. On the other hand, a change of the specimen may be observed in a gaseous environment.

When being observed in the gaseous environment, as disclosed by JP-2000-133186-A, the specimen holder may include a pair of grids between which the specimen is arranged and a gas is supplied and discharged.

In an electron microscope for real-time observation of a reaction of the specimen in a high temperature and an specific gaseous environment, as disclosed by JP-shou-51-267-A, the specimen holder may include a specimen chamber isolated by a thin film from a vacuumed environment to keep the gaseous environment surrounding the specimen, a pipe arrangement for introducing a gaseous matter into the specimen chamber and a mechanism for heating the specimen so that various reactions of the specimen are observed while the specimen is kept under the specific gaseous environment and heated.

Further, as disclosed by JP-2003-187735-A, a capillary tube may be arranged to blow the gaseous matter toward a heater for heating the specimen to observe the reaction of the specimen against the gaseous matter in the high temperature.

Further, another prior art as disclosed by JP-2002-289129-A, a nitrogen gas may be introduced into a precautionary discharge chamber before the specimen is transferred into a vacuumed device so that nitrogen gas molecule is absorbed by a surface of the specimen to be prevented from being contaminated when being irradiated with an electron beam.

Further, another prior art as disclosed by JP-hei-8-273572-A, a refrigerant storage for containing a refrigerant to cool the specimen may be arranged in the vicinity of the specimen holder so that the specimen is observed while being cooled.

Further, another prior art as disclosed by JP-hei-06-232238-A, JP-hei-06-243810-A and JP-hei-8-243572-A, in a specimen handling device, a container may contain the specimen holder so that the specimen holder is transferred between treating devices while the temperature of the specimen is controlled in a vacuumed or gas-purged environment.

Further, another prior art as disclosed by JP-2001-305028-A, the charged particle beam system may include a mechanism for heating the specimen to generate a reaction of a part of the specimen and a mechanism for blowing with a gas the part of the specimen to be cooled rapidly so that a process of the reaction is observed, and subsequently, the part of the specimen is highlighted by a focused ion beam to be observed by a transmission electron microscope.

### BRIEF SUMMARY OF THE INVENTION

In the above prior art, since the vacuumed environment and the gaseous environment are isolated from each other and a structure is complicated, such structure cannot be arranged in a narrow gap of a generally used high resolution objective lens so that a high resolution observation is difficult.

Further, in the another prior art, there is a problem of that a drift of the specimen and a directionality of the reaction caused by the gas flow are not considered.

Further, in the another prior art, there is a problem of that the contamination of the specimen when being transferred toward the observing device is not considered.

Further, there is a problem of that an irregularity in density of the gaseous environment is considered so that the reaction to be observed is not constant and a relationship between the gaseous pressure and the reaction is not correctly obtained.

Further in the another above prior art, a prevention of forming ice on the specimen when the specimen is cooled in the gaseous environment and the specimen is cooled by the gas is not considered.

Further in the another above prior art, there is a problem of that the gaseous pressure in the container containing the specimen holder needs to be contained so that a time period therefor is elongated and an amount of the gas is increased.

Further in the another above prior art, the gas with which the part of the specimen heated for the reaction is blown does not surround the specimen as the gaseous environment.

Therefore, an object of the present invention is to provide a charged particle beam device and a specimen holder for the charged particle beam device, by which a specimen is observed in a small gaseous environment volume formed by a small amount of gas with a simple structure.

Further, another object of the present invention is to provide a charged particle beam device and a specimen holder for the charged particle beam device, by which the specimen is observed without a drift of the specimen in the gaseous environment regarding, for example, a reaction process such as oxidation, reduction, crystal growth or the like of atomic level, of the specimen caused by being heated to a high temperature.

An object of the present invention is to provide a charged particle beam device and a specimen holder for the charged particle beam device, in which an evenness in density of the gaseous environment is obtained so that the reaction process of atomic level in the high temperature gas is observed without the directionality.

Another object of the present invention is to provide a specimen holder for the charged particle beam device, by which the specimen is observed and transferred without being oxidized or contaminated.

Another object of the present invention is to provide a specimen holder for the charged particle beam device, by which ice is prevented from being formed on the specimen to be cooled when the specimen is transferred and the cooled specimen is observed.

Another object of the present invention is to provide a charged particle beam device and a specimen holder for the charged particle beam device, in which the specimen is observed in an atmosphere of small volume formed in a vacuumed device.

Another object of the present invention is to provide a specimen holder for the charged particle beam device, by which a surface of the specimen is kept clean when being transferred toward the observing device just after being treated by a focused iron beam treatment device.

According to the invention, the above object is achieved by a charged particle beam device including a mechanism for blowing with a gas a part of the specimen to be observed wherein small flow rate gas blowing openings are arranged in the vicinity of the specimen to be opposed to each other through the specimen.

The another above object is achieved by using the gas of nitride.

The another above object is achieved in the charged particle beam device and the specimen holder for the charged particle beam device, by a mechanism for heating the specimen is arranged at a specimen holding area at which no gas flow exists.

The another above object is achieved in the charged particle beam device and the specimen holder for the charged particle beam device, by a mechanism for cooling the specimen.

The another above object is achieved in the charged particle beam device and the specimen holder for the charged particle beam device, by a mechanism for cooling the specimen wherein a gas to be introduced is the air.

The another above object is achieved in the charged particle beam device and the specimen holder for the charged particle beam device, by a mechanism for cooling the specimen wherein the gas to be introduced includes nitrogen.

The another above object is achieved by a mechanism for blowing with nitrogen gas continuously a part of the specimen just after being treated by a focused iron beam.

According to the invention, an dynamic observation in atomic level of a specimen is carried out with an electron beam device in a gaseous environment of small volume surrounding the specimen while a small gas flow rate prevents a vacuumed condition in the electron beam device from being deteriorated or in the gaseous environment while being heated or cooled, and the specimen is transferred in the atmosphere while keeping the environment surrounding the specimen.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWINGS

FIG. 1 is a partially cross sectional view showing a basic structure of a charged particle beam device as an embodiment of the invention.

FIG. 2A is a partially cross sectional view showing a specimen chamber of the charged particle beam device as the embodiment of the invention.

FIG. 2B is an enlarged oblique projection view showing a specimen holder for the charged particle beam device as the embodiment of the invention.

FIG. 3A is a schematic side view showing a condition in the embodiment of the invention.

FIG. 3B is a schematic upper view showing a condition in the embodiment of the invention.

FIG. 4 is a schematic upper view showing a condition in another embodiment of the invention.

FIG. 5A is a partially cross sectional view showing a specimen chamber for the charged particle beam device as another embodiment of the invention.

FIG. 5B is an enlarged oblique projection view showing the specimen holder for the charged particle beam device as the another embodiment of the invention.

FIG. 6A is a partially cross sectional view showing a specimen chamber for the charged particle beam device as another embodiment of the invention.

FIG. 6B is an enlarged oblique projection view showing the specimen holder for the charged particle beam device as the another embodiment of the invention.

FIG. 7A is a partially cross sectional view showing a specimen chamber for the charged particle beam device as another embodiment of the invention.

FIG. 7B is an enlarged oblique projection view showing the specimen holder for the charged particle beam device as the another embodiment of the invention.

FIG. 8A is a side view showing a specimen holder as another embodiment of the invention commonly usable for a focused iron beam device and an electron beam device.

FIG. 8B is an enlarged front view showing the specimen holder as the another embodiment of the invention commonly usable for the focused iron beam device and the electron beam device.

FIG. 8C is a front view of a pressing member for the specimen holder as the another embodiment of the invention commonly usable for the focused iron beam device and the electron beam device.

FIG. 9A is an oblique projection view showing an operation of the embodiment shown in FIGS. 8A-8C.

FIG. 9B is an oblique projection view showing an operation of the embodiment shown in FIGS. 8A-8C.

### DETAILED DESCRIPTION OF THE INVENTION

Hereafter, embodiments of the invention will be described with making reference to the drawings.

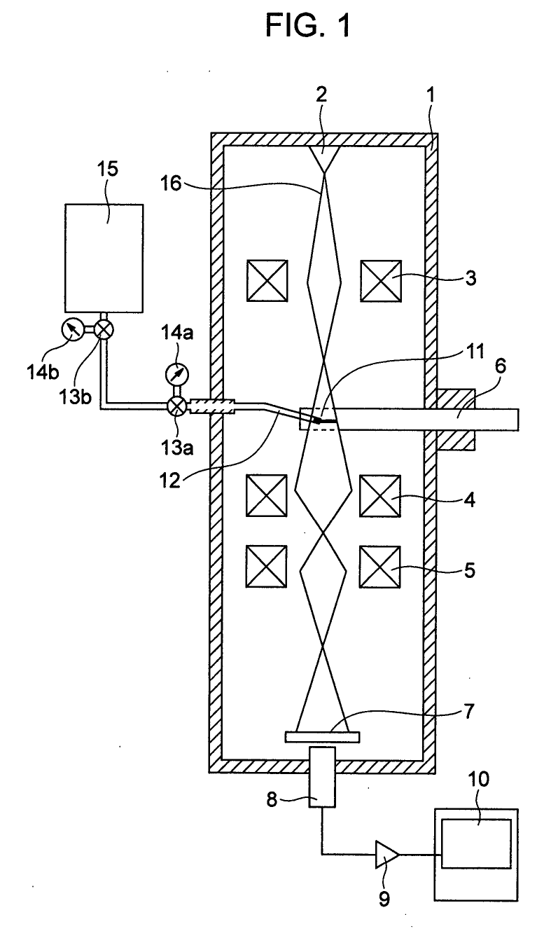

FIG. 1 is a partially cross sectional view showing a charged particle beam device 1 as an embodiment of the invention. A column of the charged particle beam device 1 includes an electron gun 2, a condenser lens 3, an objective lens 4 and a projective lens 5. A specimen holder 6 is arranged between the condenser lens 3 and the objective lens 4. A fluorescent screen 7 is arranged under the projective lens 5, and a TV camera 8 is arranged under the fluorescent screen 7. The TV camera 8 is connected to an image display 10 through a signal amplifier 9. A specimen 11 is mounted on the specimen holder for the electron microscope. A gas supply pipe 12 is arranged to oppose the specimen to be blown with a gas. The gas supply pipe 12 is connected to a gas container 15 through gaseous pressure valves 13a and 13b and flow meters 14a and 14b. An electron beam 16 generated by the electron gun 2 is condensed by the condenser lens 3 to be applied to the specimen 11. The electron beam 16 passing through the specimen 11 is focused by the objective lens 4 to form an image, and the image is enlarged by the projective lens 5 to be projected onto the fluorescent screen 7. Alternatively, the fluorescent screen 7 is moved upward so that the image is projected onto the TV camera 8 to display the transmitted image on a display 10.

A condition of a reaction of the specimen blown with the gas of low flow rate is observed through the transmitted image projected on the fluorescent screen or TV camera.

Incidentally, in the above case, the transmission electron microscope for the transmitted electronic image is described, but the invention is applicable to a scanning electron microscope for a secondary electron image. The scanning electron microscope does not need to include the projective lens, and scans a surface of the specimen 11 with a narrowed electron beam having an incident energy not more than tens of KeV to detect the secondary electron emitted from the surface of the specimen 11. Therefore, the condition of reaction of the surface of the specimen 11 in the gaseous environment can be observed.

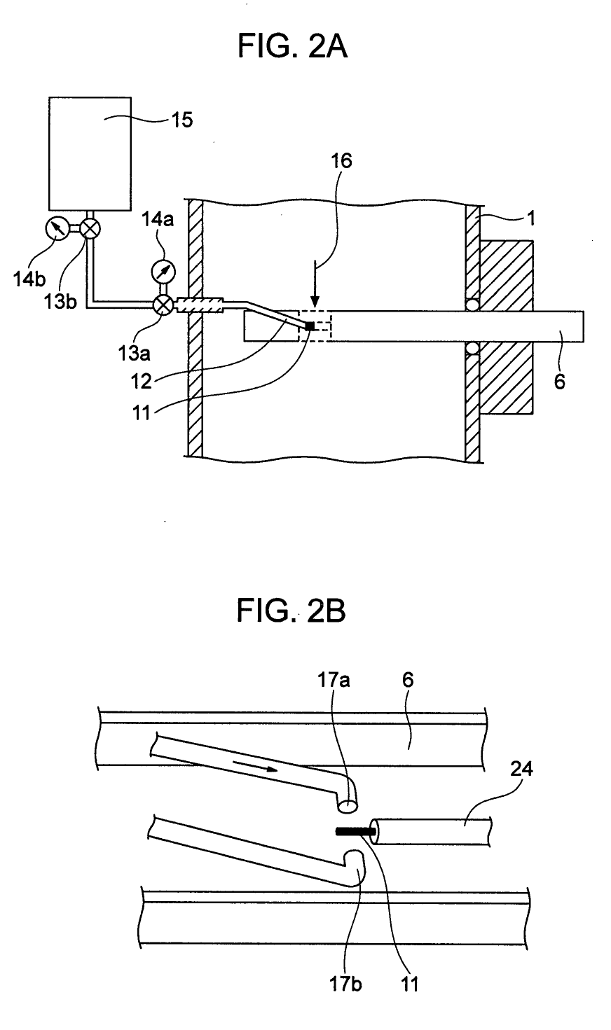

FIG. 2A is a partially cross sectional view showing a specimen chamber of the charged particle beam device as the embodiment of the invention, and FIG. 2B is an enlarged oblique projection view showing a specimen holder for the charged particle beam device as the embodiment of the invention. The gas supply pipe 12 is mounted on a specimen chamber of the charged particle beam device 1 while being prevented from contacting the holder. Further, gas spout openings 17a and 17b of the gas supply pipe 12 are arranged to oppose to each other through the specimen 11, and the specimen is set at a position where gas flows from the respective gas spout openings 17a and 17b contact each other. Flow rates thereof are adjusted by the gaseous pressure valves 13 and the flow meters 14. The specimen chamber of the charged particle beam device 1 has a vacuumed condition of normally 1×10⁻⁵ Pa. Since the specimen 11 has a small size, the flow rates of the gas for the reaction may be small. The gaseous flows of identical pressure supplied from the gas supply pipes 12 opening to opposed to each other through the specimen 11 form at the specimen 11 the gaseous environment where a gaseous flow velocity is substantially zero. Therefore, the specimen 11 surrounded by the gaseous environment of small volume can be observed.

In this case, non-magnetic tubes form parts of the gas supply pipes 12 which parts include the gas spout openings 17a and 17b and through which parts the electron beam 16 passes, so that a magnetic field is prevented from affecting the lens and so forth, and the other parts of the gas supply pipes 12 may include cushioning material to be isolated from a vibration source. Further, although the gas spout openings 17a and 17b are arranged on an imaginary line perpendicular to a longitudinal axis of the holder 6 in FIG. 2B, the gas spout openings 17a and 17b arranged to be opposed to each other through the specimen 11 may be arranged on another imaginary line parallel to the longitudinal axis of the holder 6.

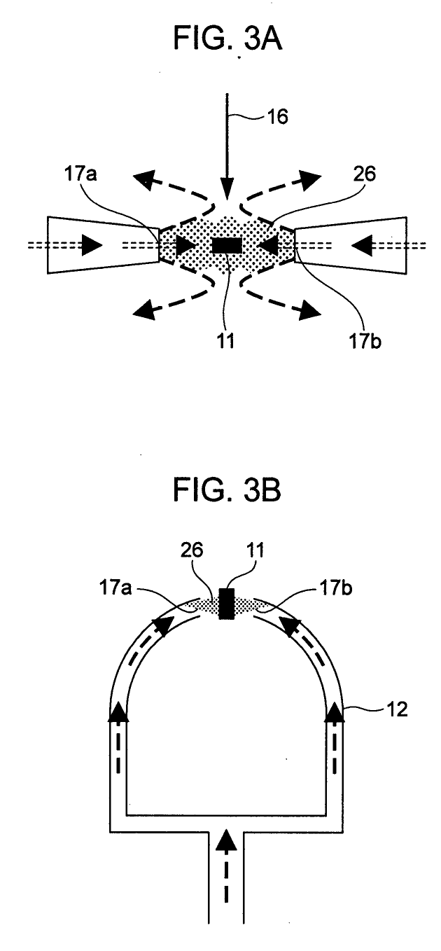

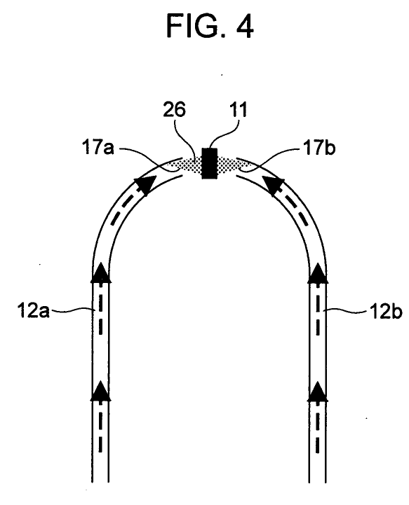

FIG. 3B is a schematic upper view showing a condition in the embodiment of the invention, and FIG. 4 is a schematic upper view showing a condition in another embodiment of the invention.

The gas supply pipes 12 of identical shape face to each other through the specimen 11 with an identical distance between the specimen and each of the gas supply pipes 12, and the gaseous flows of identical pressure are supplied to the specimen 11 from the gas spout openings 17a and 17b respectively. Therefore, the gas is prevented from flowing on a region of the specimen 11 to be observed so that a drift of the specimen 11 caused by the gaseous environment is prevented.

FIG. 4 is a schematic upper view showing a condition in another embodiment of the invention. Differently from FIGS. 3A and 3B showing the gas supply pipes 12 having the gas spout openings 17a and 17b respectively and diverging from the gas supply pipe 12, gas supply pipes 12a and 12b having the identical shape and arranged to opposed to each other through the specimen may be used.

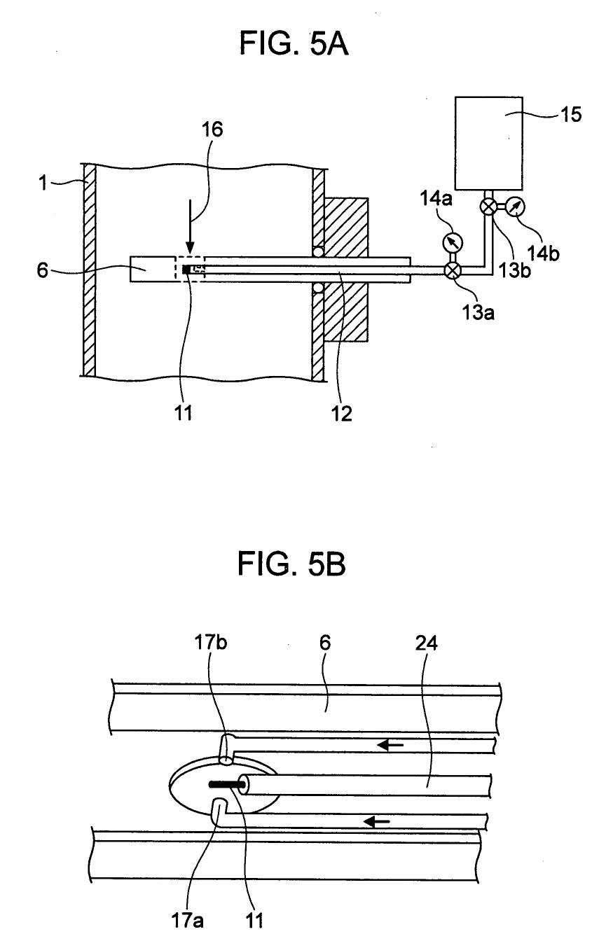

FIG. 5A is a partially cross sectional view showing a specimen chamber for the charged particle beam device as another embodiment of the invention, and FIG. 5B is an enlarged oblique projection view showing the specimen holder for the charged particle beam device as the another embodiment of the invention. Differently from the first and second embodiment wherein the gas supply pipe 12 is separated from the holder 6 for the specimen 11, the gas supply pipe 12 is incorporated in the specimen holder 6. Such specimen holder, when the gas container 15 is of a compact size, can be easily transferred between generally used charged particle beam devices while keeping the gaseous environment for the transferred specimen 11. In this case, when the gas is, for example, nitrogen gas, the specimen can be transferred between a preliminary treatment device and an observing device while being prevented from contacting the atmosphere, so that an oxidation of the specimen in the atmosphere and a contamination of the specimen caused by a water content absorbed from the atmosphere are prevented to obtain an accuracy in observation and analysis.

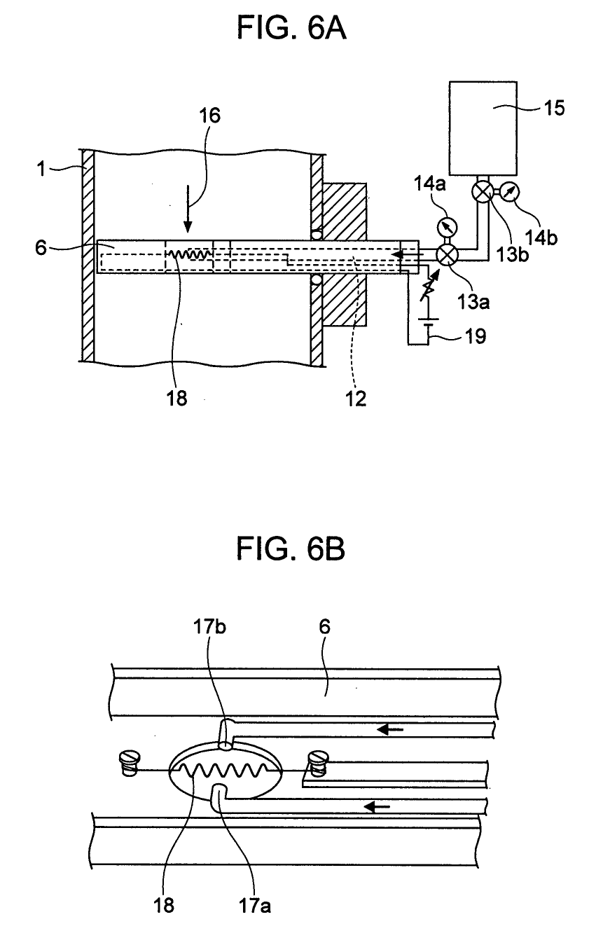

FIG. 6A is a partially cross sectional view showing a specimen chamber for the charged particle beam device as another embodiment of the invention, and FIG. 6B is an enlarged oblique projection view showing the specimen holder for the charged particle beam device as the another embodiment of the invention. A heater 18 and the gas supply pipe 12 are mounted on the specimen holder 6. The heater 18 for heating the specimen on the specimen holder 6 is connected to a heater electric source 19 at the outside of the charged particle beam device 1 through an electric wiring. In this case, the specimen 11 is capable of directly contacting the heater 18. The heater 18 for heating the specimen is electrically energized to increase the temperature of the specimen 11 to be observed. The temperature of the specimen 11 is adjusted by the heater electric source 19 changing a voltage to be applied to the heater 18. The gas spout openings 17a and 17b are arranged to be opposed to each other through the heater 19. The reaction of the specimen 11 heated to the high temperature is observed while being blown with the gas. Further, since the gas flow velocity at the observing position is zero, the reaction in atomic level of the specimen in the high temperature can be observed without the directionality of the specimen in the reaction while preventing the drift of the specimen 11.

In FIGS. 6A and 6B, the gas supply mechanism 12 is mounted on the specimen holder 6, but, the gas supply mechanism 12 may be mounted on the charged particle beam device 1 as shown in the embodiment of FIGS. 1, 2A and 2B to be combined with the specimen holder with the heater so that the specimen 11 is observed in the gaseous environment of high temperature.

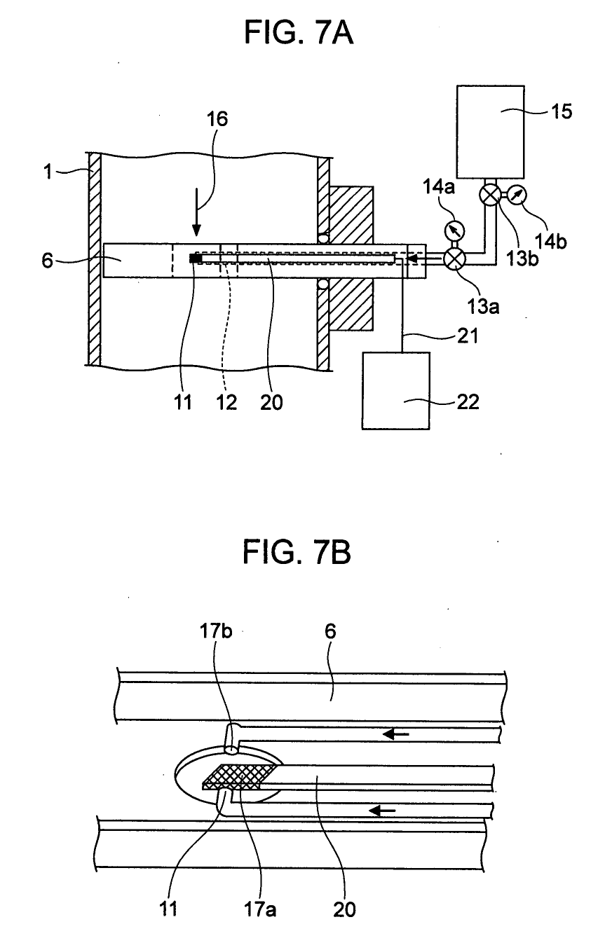

FIG. 7A is a partially cross sectional view showing the specimen holder 6 with a gas reaction generating mechanism mounted in the specimen chamber of the charged particle beam device 1, and FIG. 7B is an enlarged oblique projection view showing a specimen mounting portion of the specimen holder. The specimen 11 is set on a front end of a thermally conductive bar 20 connected to a liquefied nitrogen container 22 through a thermally conductive line 21. The gas spout openings 17a and 17b are arranged to be opposed to each other through the specimen 11 to be cooled by the gas supplied from the gas spout openings 17a and 17b so that the condition of the specimen 11 is observed in the cooled gaseous environment.

The gas supply mechanism is mounted on the specimen holder 6 as shown in FIGS. 7A and 7B, but, as shown in the embodiment of FIGS. 1, 2A and 2B, the gas supply mechanism may be mounted on the charged particle beam device 1 to be combined with the specimen holder with the cooler so that the condition of the specimen 11 is observed in the cooled gaseous environment.

Further, in the embodiment shown in FIGS. 7A and 7B, the specimen frozen at the outside of the charged particle beam device 1 is introduced into the specimen chamber of the charged particle beam device 1 vacuumed to about 1×10⁻⁵ Pa, and subsequently after the temperature of the specimen returns to normal temperatures, the air of small flow rate is supplied from the gas spout openings 17a and 17b to make the gaseous environment surrounding the specimen equal to the atmospheric environment so that a microstructure of animate beings or material is observed in the environment equal to the atmospheric environment.

Further, in the embodiment shown in FIGS. 7A and 7B, the gas supplied when the specimen is cooled, transferred or observed is made nitrogen gas prevented from including the water content, so that frost is prevented from being formed on the specimen to prevent a quality of the image from being deteriorated.

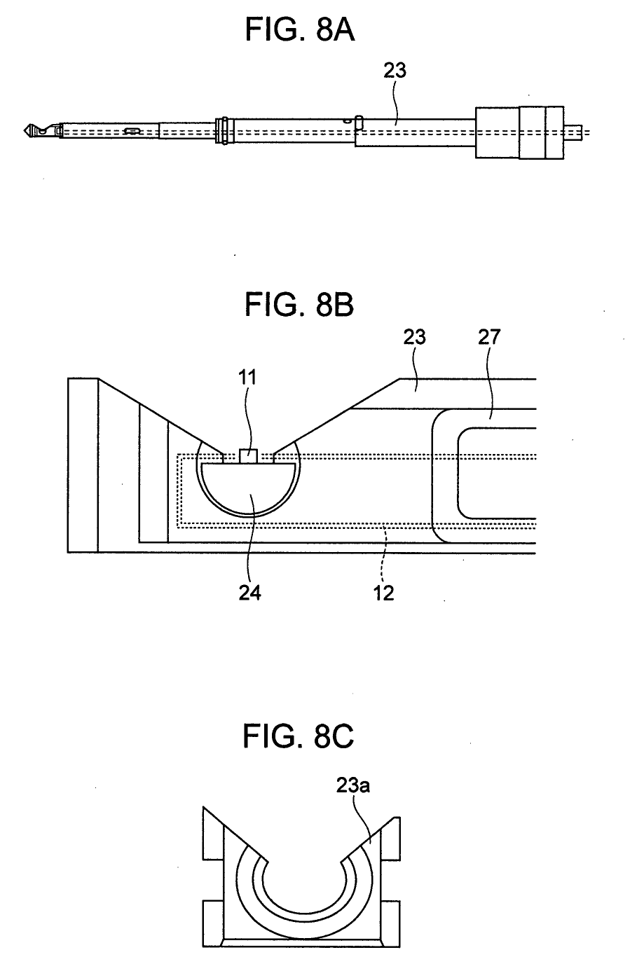

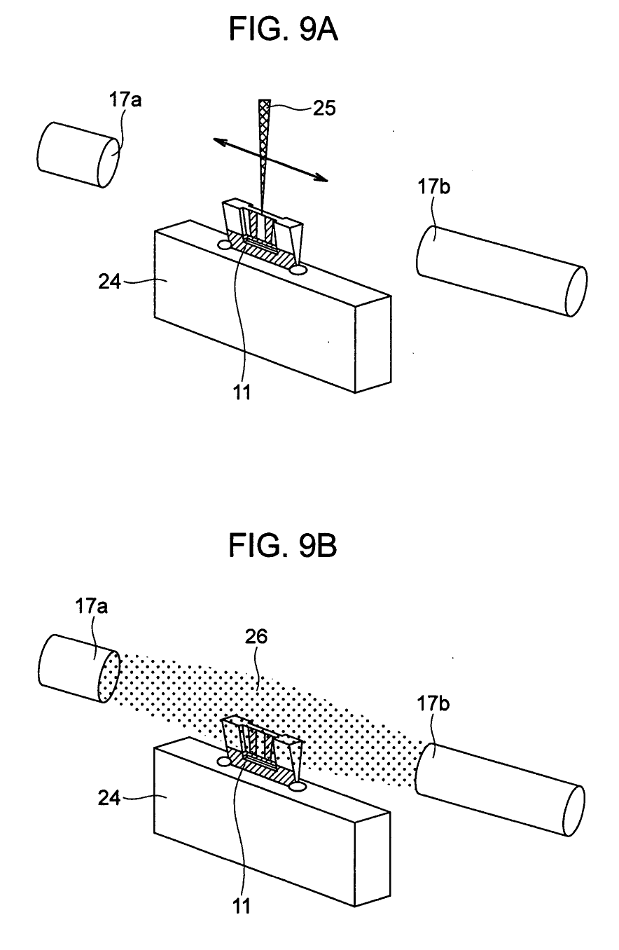

FIG. 8A is a side view showing a specimen holder 23 with the gas supply mechanism commonly usable for a focused iron beam (FIB) device and an electron beam device, FIG. 8B is an enlarged front view showing the specimen mounting portion of the specimen holder 23 commonly usable for the focused iron beam device and the electron beam device, and FIG. 8C is a front view of a specimen pressing member 23a. As shown in FIGS. 8A, 8B and 8C, the gas supply mechanism including the gas spout openings 17a and 17b arranged to be opposed to each other through the specimen 11 is mounted on the specimen holder 23 commonly usable for the focused iron beam device and the electron beam device. After the specimen is set as shown in FIG. 8B, the specimen pressing member 23a is positioned on the specimen so that a specimen table 24 with the specimen is fixed by a specimen pressing spring 27. The gas supply pipe including the gas spout openings 17a and 17b arranged to be opposed to each other through the specimen 11b may be incorporated in the specimen holder 23 as shown in the drawings, or alternatively, the gas spout openings 17a and 17b may arranged on the surface of the holder 23. FIGS. 9A and 9B show operations of the embodiment shown in FIGS. 8A-8C. After the specimen 11 mounted on the specimen table 24 is treated by a focused iron beam 25 to form a thin layer thereon, an exposed surface of the specimen 11 is blown with the gas prevented from including the water content and oxygen, for example, the nitrogen gas so that the specimen surrounded by the nitrogen gas environment 26 is transferred to the observation device while preventing the surface 25 of the specimen 11 treated by the FIB from being oxidized or contaminated.

It should be further understood by those skilled in the art that although the foregoing description has been made on embodiments of the invention, the invention is not limited thereto and various changes and modifications may be made without departing from the spirit of the invention and the scope of the appended claims.

1. A charged particle beam system for observing a specimen in a gas, comprising,
an electron beam source for generating a primary electron beam,
an electron beam controller for condensing the primary electron beam to be applied to the specimen,
a chassis for keeping a vacuumed condition in a region through which the primary electron beam passes,
a specimen holder at least partially supported by the chassis to hold the specimen thereon, and
a gas supplier at least partially supported by the chassis to supply the gas to the specimen,
a first gas spout opening for discharging the gas of small flow rate toward the specimen in a first direction, and
a second gas spout opening for discharging the gas of small flow rate toward the specimen in a second direction different from the first direction.

2. A charged particle beam system for observing a specimen in a gas, comprising,
an electron beam source for generating a primary electron beam,
an electron beam controller for condensing the primary electron beam to be applied to the specimen,
a chassis for keeping a predetermined vacuumed condition in a region through which the primary electron beam passes,
a specimen holder at least partially supported by the chassis to hold the specimen thereon,
a gas supplier at least partially supported by the chassis to supply the gas to the specimen,
a first gas spout opening for discharging the gas toward the specimen along a first direction while a flow rate of the gas discharged from the first gas spout opening is sufficiently small for satisfying the predetermined vacuumed condition, and
a second gas spout opening for discharging the gas toward the specimen in a second direction while a flow rate of the gas discharged from the second gas spout opening is sufficiently small for satisfying the predetermined vacuumed condition,
wherein the first and second gas spout openings being opposed to each other along the first direction, and the first and second directions are opposite to each other.

3. The charged particle beam system according to claim 1, wherein the gas supplier further includes a controller for adjusting the flow rate of the gas discharged from the first gas spout opening and the flow rate of the gas discharged from the second gas spout opening so that the gas discharged from the first gas spout opening and the gas discharged from the second gas spout opening encounter each other through the specimen and in the vicinity of the specimen.

4. The charged particle beam system according to claim 2, wherein the gas supplier includes a controller for adjusting the flow rate of the gas discharged from the first gas spout opening and the flow rate of the gas discharged from the second gas spout opening so that the gas discharged from the first gas spout opening and the gas discharged from the second gas spout opening encounter each other through the specimen and in the vicinity of the specimen.

5. The charged particle beam system according to claim 1, wherein the gas supplier includes a controller for adjusting the flow rate of the gas discharged from the first gas spout opening and the flow rate of the gas discharged from the second gas spout opening so that a boundary face at which the gas discharged from the first gas spout opening and the gas discharged from the second gas spout opening encounter each other to prevent an apparent flow of the gas is arranged on a main surface of the specimen.

6. The charged particle beam system according to claim 1, wherein the first and second gas spout openings are arranged so that the gas discharged from the first gas spout opening and the gas discharged from the second gas spout opening encounter each other through the specimen and in the vicinity of the specimen to form a gaseously pressurized area on the specimen and in the vicinity of the specimen.

7. The charged particle beam system according to claim 1, wherein the first and second gas spout openings are mounted on the gas supplier.

8. The charged particle beam system according to claim 1, wherein the first and second gas spout openings are mounted on the specimen holder.

9. The charged particle beam system according to claim 1, wherein the gas is nitrogen to prevent the specimen from being oxidized and contaminated when the specimen is observed.

10. The charged particle beam system according to claim 1, wherein the specimen holder includes a heater for heating the specimen so that a drift of the specimen is prevented when a reaction of the specimen with respect to the gas discharged from the gas supplier is observed.

11. The charged particle beam system according to claim 2, wherein the specimen holder includes a heater for heating the specimen so that a drift of the specimen is prevented when a reaction of the specimen with respect to the gas discharged from the gas supplier is observed.

12. The charged particle beam system according to claim 1, further comprising a cooler for cooling the specimen so that the specimen cooled by the cooler in the gas is observed.

13. The charged particle beam system according to claim 1, further comprising a display for displaying an electron beam image formed on the basis of signals generated from the electron beam passing through the specimen and received by a fluorescent screen.

14. The charged particle beam system according to claim 1, further comprising a display for displaying an electron beam image formed on the basis of secondary signals generated from the specimen scanned with the electron beam.

15. The charged particle beam system according to claim 1, wherein a temperature of the specimen is kept at a room temperature and the air is introduced so that a microstructure of at least one of organism and high-polymer in the atmosphere is analyzed.

16. The charged particle beam system according to claim 1, wherein the gas is prevented from including water content to prevent frost from being formed on the specimen being observed.

17. A specimen holder for a charged particle beam device including an electron beam source for generating a primary electron beam, an electron beam controller for condensing the primary electron beam to be applied to the specimen, a chassis for keeping a predetermined vacuumed condition in a region through which the primary electron beam passes, and a gas supplier at least partially supported by the chassis to supply the gas to the specimen, comprising,
a first gas spout opening for discharging the gas supplied from the gas supplier along a first direction while a flow rate of the gas discharged from the first gas spout opening is sufficiently small for satisfying the predetermined vacuumed condition, and
a second gas spout opening for discharging the gas in a second direction while a flow rate of the gas discharged from the second gas spout opening is sufficiently small for satisfying the predetermined vacuumed condition,
wherein the first and second gas spout openings being opposed to each other along the first direction, and the first and second directions are opposite to each other.

18. The specimen holder according to claim 17, further comprising a controller for adjusting the flow rate of the gas discharged from the first gas spout opening and the flow rate of the gas discharged from the second gas spout opening so that the gas discharged from the first gas spout opening and the gas discharged from the second gas spout opening encounter each other through the specimen and in the vicinity of the specimen.

19. The specimen holder according to claim 17, further comprising a controller for adjusting the flow rate of the gas discharged from the first gas spout opening and the flow rate of the gas discharged from the second gas spout opening so that a boundary face at which the gas discharged from the first gas spout opening and the gas discharged from the second gas spout opening encounter each other to prevent an apparent flow of the gas is arranged on a main surface of the specimen.

20. The specimen holder according to claim 17, further comprising a heater for heating the specimen so that a drift of the specimen is prevented when a reaction of the specimen with respect to the gas discharged from the gas supplier is observed.

21. The specimen holder according to claim 17, further comprising a cooler for cooling the specimen so that the specimen cooled by the cooler in the gas is observed.

22. The specimen holder according to claim 17, wherein the gas is prevented from including water content to prevent frost from being formed on the specimen when being transferred and observed.

23. The specimen holder according to claim 17, wherein a surface of the specimen is blown continuously with nitrogen gas as the gas after the surface is treated by a focused iron beam so that the surface is prevented from absorbing water content to be deteriorated and oxidized when the specimen holder is transferred in the atmosphere to observe the surface kept clean.
